(19) United States
(12) Patent Application Publication
(10) Pub. No.: US 2011/0312498 A1
(43) Pub. Date: Dec. 22, 2011

(54) FAULT CURRENT LIMITER

(75) Inventor: Kasegn D. Tekletsadik, Middleton, MA (US)

(73) Assignee: VARIAN SEMICONDUCTOR EQUIPMENT ASSOCIATES, INC., Gloucester, MA (US)

(21) Appl. No.: 13/162,107

(22) Filed: Jun. 16, 2011

Related U.S. Application Data
(60) Provisional application No. 61/356,285, filed on Jun. 18, 2010.

(51) Int. Cl. H01L 39/02; H02H 9/02

(52) U.S. Cl. 505/150; 361/19

(57) ABSTRACT

A fault current limiter that maximizes transient stability by minimizing the power swing experienced by the generator during a fault condition is disclosed. A superconducting fault current limiter (SCFCL) is used, whereby the impedance of the SCFCL changes in the presence of a fault. In parallel with the SCFCL is a shunt impedance, which is the impedance seen by the generator during the fault. By decreasing the ratio of the reactance of the shunt impedance to its resistance, the stability of the power system may be enhanced.

This application claims priority of U.S. Provisional Patent Application Ser. No. 61/356,285, filed Jun. 18, 2010, the disclosure of which is incorporated herein by reference in its entirety.

### FIELD

This disclosure relates to fault current limiters, and more particularly to fault current limiters used to improve transient stability of a power system.

### BACKGROUND

A fault current limiter is a device that limits fault currents in a power system. The power system may include transmission and distribution networks to deliver power to differing loads. A fault current is an abnormal current in an electrical circuit due to a fault such as a short circuit resulting in a short circuit current. A fault current may occur due to severe weather damaging power lines and components, e.g., lighting striking the power system. When faults occur, a very small load appears instantaneously. The network, in response, delivers a large amount of current (i.e. fault current) to this load or, in this case, the faults. This surge or fault current condition is undesirable as the condition may damage the network or equipment connected to the network. In particular, the network and the equipment connected thereto may burn or, in some cases, explode.

Turning to FIG. 1, a circuit diagram of a power system 100 having a , conventional fault current limiter (FCL) 106 is illustrated. The conventional power system includes an AC power generator 102 to provide power to a load 110. The FCL 106 may be coupled in series with the power generator 102 and a downstream circuit breaker 108. A fault condition may occur at location 112 illustrated as an inadvertent path to ground.

Turning to FIG. 2, a timing diagram illustrates the general operation of the FCL 106. During a steady state time interval, the power generator 102 supplies the load 110 and the circuit breaker 108 is in a closed position. The FCL 106 generally has little to no resistance in the steady state mode and allows AC current (i_{ac}) to flow to the load 110. During a fault interval, a fault may occur at location 112. In response, the power generator 102 attempts to deliver a large amount of fault current. The FCL 106 essentially limits the fault current by reducing the peak to peak value of the fault current provided to the load 110 and potentially other components during this fault time interval before the circuit breaker 108 can open. Since it is important to maintain very low resistance during normal operation, typically current limiting is provided by introducing a larger reactance. Typically, the magnitude of this reactance is at least thirty times larger than the resistance of the FCL 106. During the next post fault time interval, the circuit breaker 108 opens and no current is provided.

The FCL 106 may be a superconducting fault current limiter (SCFCL). In general, a SCFCL has a superconductor that is normally in a superconducting state with essentially a negligible resistance during the steady state time interval. During a fault condition, the superconductor transitions from the superconducting state to a normal conducting state (quench). This extra resistance reduces or limits the fault current during the fault condition time interval.

A conventional FCL 106 is primarily dedicated to the fault current limiting function only. An equivalent impedance of the FCL 106 is given in Cartesian form by Z_{FCL}=R_{FCL}+jX_{FCL}, where the real part of impedance is the resistance (R_{FCL}) and the imaginary part is the reactance (X_{FCL}). The SI unit for both the resistance (R_{FCL}) and reactance (X_{FCL}) is the ohm. As described above, the ratio of reactance to resistance or the X_{FCL}/R_{FCL} ratio is greater than 30 for the conventional FCL 106. In most instances, it is typically as high as 100-300.

Turning to FIG. 3, a graph of plots of power versus angles are given for power transfer from the generator 102 to the load 110 during certain time intervals. These time intervals include the steady state power (Pess) during the steady state time interval, power (Pef) during the fault time interval, and power (Pepf) during the post fault interval once the circuit breaker 108 opens. The plots are for a conventional FCL 106 having an X_{FCL}/R_{FCL} ratio greater than 30. The power transfer from the generator 102 to the load 110 during these time intervals are given by the below equations.

$$Steady State \text{:} Pess = \frac{Vs \cdot Vr}{Xs} \cdot sin ( δ )$$

$$During Fault \text{:} Pef = {I}_{F}^{2} {R}_{FCL}$$

$$Post Fault \text{:} Pepf \approx \frac{Vs \cdot Vr}{Xs + {X}_{FCL}} \cdot sin ( δ )$$

As shown in FIG. 3, the plot shows a fault condition occurring at angle δ₀. At this point, the power transfer 302 during the fault condition (represented as Pef) is significantly lower than the mechanical power (P_{M}) of the generator 102. Since R_{FCL} is small, the power transfer 302 during the fault (Pef), which is defined as the fault current squared (I_{F}²) multiplied by the resistance of the fault current limiter (R_{FCL}), is also very small and may approach 0. The difference between the mechanical power (P_{M}) and the power transfer 302 during a fault (Pef) is given by ΔP1=(P_{M}−Pef)˜P_{M} in this instance. At angle δ₁, the circuit breaker opens. The area defined between these two angles (δ₀ and δ₁) and between P_{M} and Pef, is labeled A1. This area, A1, is the energy gained when the generator is accelerating during the fault. For stable power system operation, this area must equal the area, A2, which is the energy lost after the fault has been cleared. The area A2 is defined as the region between the mechanical power (P_{M}) and the power transfer post fault (Pepf) and between angles δ₁ and δ₂. The angle δ₂ is defined as the angle at which the area of A2 is equal to the area of A1. For stable operation, δ₂ must be less than 180°. Therefore, the area of region A1 is critical to the stability of the system. The speed at which the fault is detected, as measured by δ₁-δ₀, is one criteria to minimizing instability. The second important parameter is the power swing (ΔP1) during the fault condition. Large power swings adversely impact transient stability of the power system.

Accordingly, there is a need in the art for a fault current limiter that overcomes the above-described inadequacies and shortcomings.

### SUMMARY

A fault current limiter that maximizes transient stability by minimizing the power swing experienced by the generator during a fault condition is disclosed. A superconducting fault current limiter (SCFCL) is used, whereby the impedance of the SCFCL changes in the presence of a fault. In parallel with the SCFCL is a shunt impedance, which is the impedance seen by the generator during the fault. By decreasing the ratio of the reactance of the shunt impedance to its resistance, the stability of the power system may be enhanced.

### BRIEF DESCRIPTION OF THE DRAWINGS

For a better understanding of the present disclosure, reference is made to the accompanying drawings, in which like elements are referenced with like numerals, and in which:

FIG. 1 is a circuit diagram of a power system including a conventional fault current limiter;

FIG. 2 is a timing diagram illustrating operation of the conventional fault current limiter in the system of FIG. 1;

FIG. 3 are plots of power transfer from the generator to the load of FIG. 1 with a conventional fault current limiter;

FIGS. 4A-B are circuit diagrams of a power system having a fault current limiter consistent with an embodiment of the disclosure;

FIG. 5 are plots of power transfer from the generator to the load for the embodiment shown in FIG. 4A-B; and

FIG. 6 is a schematic diagram of one embodiment of a fault current limiter consistent with the disclosure.

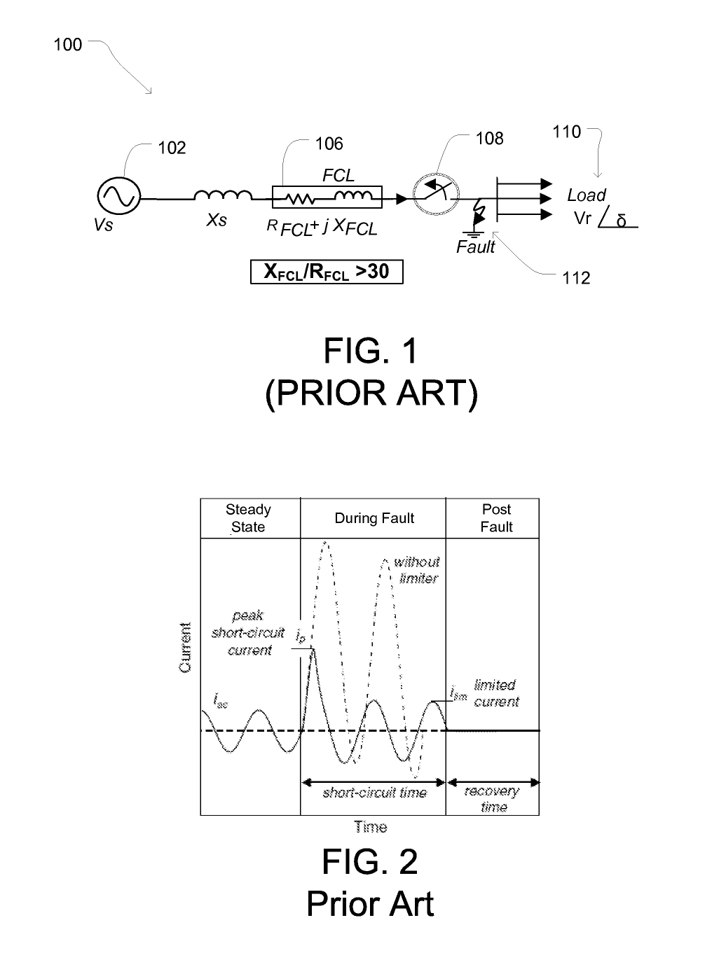

### DETAILED DESCRIPTION

The present invention will now be described more fully hereinafter with reference to the accompanying drawings, in which embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

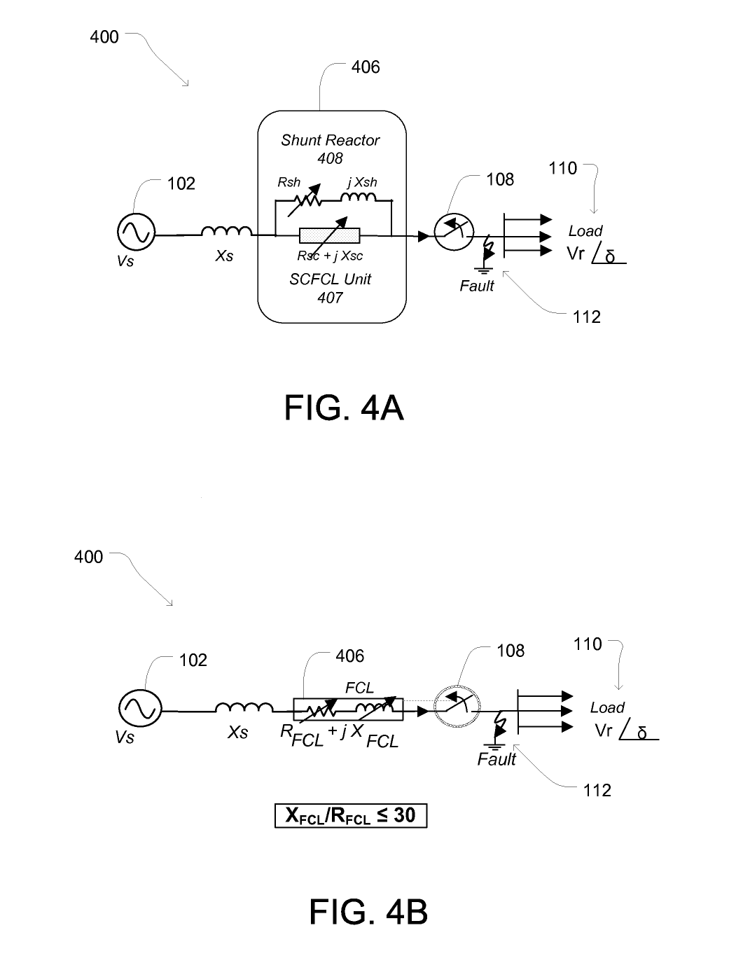

FIG. 4A is a circuit diagram of a power system 400 having a fault current limiter 406 consistent with an embodiment of the disclosure. Other components of FIG. 4 similar to FIG. 2 have like reference numerals and hence any repetitive description is omitted herein for clarity. The fault current limiter 406 is comprised of a superconducting fault current limiter 407 and a shunt reactor 408. The superconducting fault current limiter 407 has an impedance, which includes a reactance and a resistance, which may be expressed as Z_{sc}=R_{sc}+jX_{sc}. The resistance (R_{sc}) of the superconducting fault current limiter 407 changes based on current. Under normal conditions, the resistance (R_{sc}) of the SCFCL 407 is nearly zero. Under fault current conditions, the resistance (R_{sc}) of the SCFCL 407 may increase to a very large value. The shunt reactor 406 also has an impedance, which includes a resistance and a reactance, which may be expressed as Zₛₕ=Rₛₕ+jXₛₕ.

Since the SCFCL 407 and shunt reactor 408 are in parallel, an equivalent circuit can be created, where the series impedance (Z_{FCL}) is equal to R_{FCL} where Z_{FCL} is the parallel combination of Zₛₕ and Z_{sc}.

As mentioned above, under normal operation, the impedance of the superconducting fault current limiter 407 is roughly equal to 0, and therefore, the series impedance (Z_{FCL}) during normal operation is approximately equal to 0 as well. During a fault, the resistance (R_{sc}) of the SCFCL 407 may increase to a very large value, such that the series impedance (Z_{FCL}) is roughly equal the impedance of the shunt reactor (Zₛₕ=Rₛₕ+jXₛₕ).

FIG. 4B is a circuit diagram of a power system 400 having a fault current limiter 406 consistent with an embodiment of the disclosure. The shunt reactor 408 and the SCFCL 407 have been replaced with the equivalent series impedance (Z_{FCL}), as described above.

Advantageously, the fault current limiter (FCL) 406 has an X_{FCL}/R_{FCL} ratio less than or equal to 30.

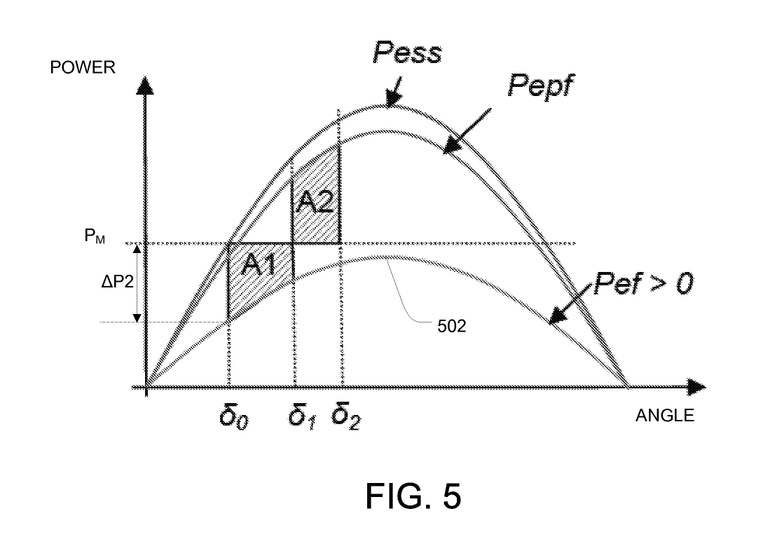

Turning to FIG. 5, a graph of plots of power versus angles are given during certain time intervals. These time intervals include the steady state power (Pess) during the steady state time interval, power (Pef) during the fault time interval, and power (Pepf) during the post fault interval once the circuit breaker 108 opens. The power transfer from the generator 102 to the load 110 during these time intervals are given by the following equations, as was presented earlier.

$$Steady State \text{:} Pess = \frac{Vs \cdot Vr}{Xs} \cdot sin ( δ )$$

$$During Fault \text{:} Pef = {I}_{F}^{2} {R}_{FCL}$$

$$Post Fault \text{:} Pepf \approx \frac{Vs \cdot Vr}{Xs + {X}_{FCL}} \cdot sin ( δ )$$

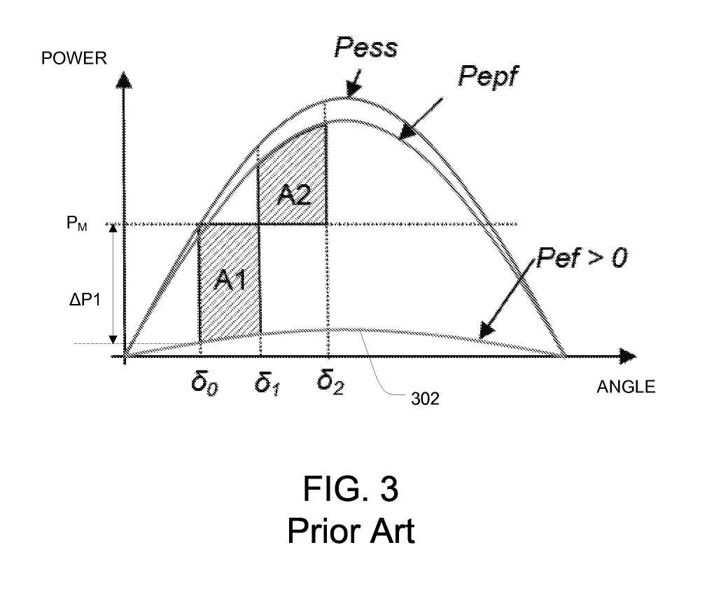

The plots are with the FCL 406 having an X_{FCL}/R_{FCL} ratio less than or equal to 30. In this case, the value of R_{FCL} was much larger than that used in FIG. 3. As a result, the plot 502 of power (Pef) during the fault is advantageously only slightly less than the mechanical power (P_{M}) of the generator 102. In this instance, the difference between the mechanical power (P_{M}) and the power transfer during a fault (Pef) is given by ΔP2=(P_{M}−Pef) which is trending towards 0. In contrast to FIG. 3, ΔP2 is much less than ΔP1. Therefore, the disturbance to the generator 102 is minimized compared to the greater disturbance shown in FIG. 3. Accordingly, transient stability is improved with the FCL 406 having an X_{FCL}/R_{FCL} ratio less than or equal to 30. In general, the FCL 406 with such a X_{FCL}/R_{FCL} ratio reduces power swings (ΔP2 is much less than ΔP1) as the I²R losses in the FCL 406 provides electrical power output during the fault as illustrated by plot 502. In other words, the lower X_{FCL}/R_{FCL} ratio of the FCL 406 instantaneously inserts a load that sinks active power. In this way, the generator 102 “sees” a minimum loss of load which promotes a more stable operation.

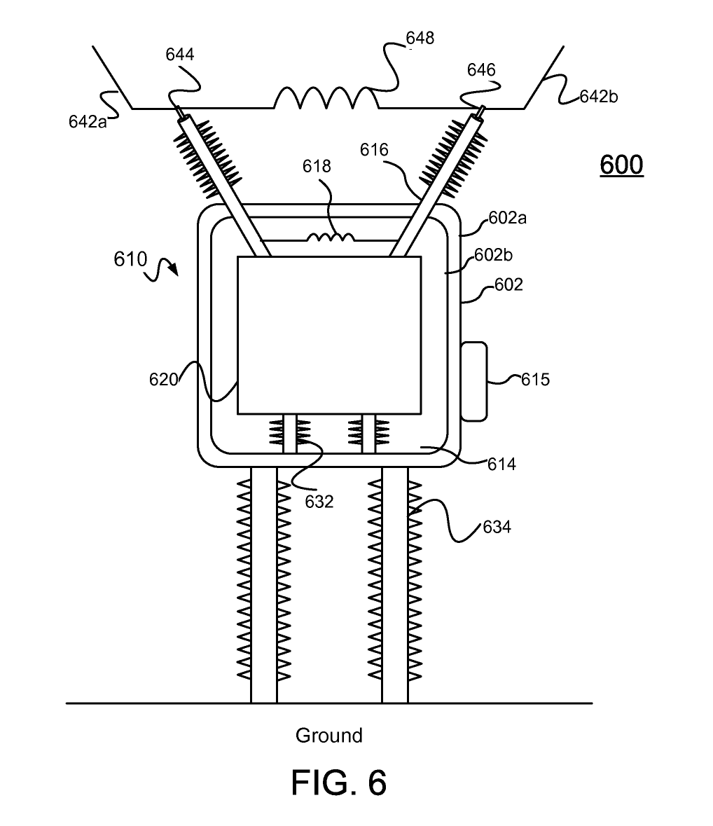

Turning to FIG. 6, a schematic diagram of a fault current limiter 600 consistent with the disclosure that can provide an X_{FCL}/R_{FCL} ratio less than or equal to 30 is illustrated. To accomplish this, one or more of the reactance and resistance of the fault current limiter may be varied to lower the X_{FCL}/R_{FCL} ratio from its conventionally higher value to a value less than or equal to 30.

In the embodiment of FIG. 6, the FCL 600 may be a superconducting fault current limiter (SCFCL) and may be described as such herein. An internal shunt reactor 618 and/or an external shunt reactor 648 may be connected as illustrated to the electrical bushings 616. Each shunt reactor 618 and 648 may be a winding fabricated of material such as copper or aluminum. The cross sectional area of one or both shunt reactors 618 and 648 may be selected so that the effective X_{FCL}/R_{FCL} ratio of the SCFCL 600 is less than or equal to 30.

The SCFL 600 may include other components such as an enclosure or tank 602 defining a chamber therein. In one embodiment, the tank 602 may be thermally and/or electrically insulating tank 602 such as those made with fiberglass or other dielectric material. In another embodiment, the tank 602 may be a metallic tank comprising inner and outer layers 602a and 602b, and a thermally and/or electrically insulating medium interposed there between. Within the tank 602, there may be one or more fault current limiting units 620 which, for the purpose of clarity and simplicity, are shown as a block. One or more superconducting circuits may be disposed in the fault current limiting units 620.

The SCFL 600 may also comprise one or more electrical bushings 616. The bushings 616 may comprise an inner conductive material (not shown) and an outer insulator. The distal end of the bushings 616 may be coupled to a respective power line 642 (642a and 642b) via terminals 644 and 646. The power lines 642 may be transmission or distribution lines of a power system. The inner conductive material in the bushings 616 may connect the terminals 644 and 646 of the bushings 616 to the fault current limiting unit 620. Meanwhile, the outer insulator is used to insulate the tank 602 from the inner conductive material, thereby allowing the tank 602 and the terminals 644 and 646 to be at different electrical potentials.

The temperature of one or more fault current limiting units 620 may be maintained at a desired temperature range by coolant 614 contained in the tank 602. In one embodiment, it may be desirable to maintain the fault current limiting units 620 at a low temperature, for example, ˜77° K. To maintain at such a low temperature range, liquid nitrogen or helium gas may be used as coolant 614. In another embodiment, it may be desirable to maintain the temperature of the one or more fault current limiting units 620 at other temperature range, and other types of coolant, in gaseous or liquid form, may also be used. For example, it may be desirable to maintain the temperature of the fault current limiting units 620 at a room temperature. In such a case, air maintained at a room temperature may also be used as the coolant 614. When introduced, the coolants 614 may enter the tank 602 via a feed line (not shown) and a port 615 coupled to the tank 602. In the present disclosure, the feed line and the port 615 may preferably be made from thermally and/or electrically insulating material. If the feed line and the port 615 do not provide grounding of the tank 602 or any component contained therein, they may be made from any type of material.

The tank 602 may be supported from the ground by an optional external support 634. Meanwhile, the fault current limiting units 620 may be supported from the tank 602 by an optional internal support 632. Those of ordinary skill in the art may recognize that both of the internal supports 632 and the external support 634 may be optional as the fault current limiting units 620 may be supported from the tank 602 by some other components. If included, each of the internal support 632 and the external support 634 may preferably be made from thermally and/or electrically insulating material.

In operation, a superconductor of the fault current limiting units 620 is in a superconducting state and the SCFCL 600 provides negligible resistance to the system under normal or steady state operating conditions. During a fault condition, the superconductor transitions from the superconducting state to a normal conducting state to add resistance which limits the fault current during the fault condition. The SCFCL 600 has an X_{FCL}/R_{FCL} ratio of equal to or less than 30 to assist with transient stability of the power system to which it is coupled.

There has thus been provided a fault current limiter with an X_{FCL}/R_{FCL} ratio of equal to or less than 30. Such a fault current limiter can improve power system transient stability significantly by damping the dynamic disturbance to the power system. In particular, such a fault current limiter may reduce power swings as the I²R losses of the fault current limiter provides electrical power during the fault. In other words, the lower X_{FCL}/R_{FCL} ratio of the fault current limiter instantaneously inserts a load that sinks active power. In this way, generators of the power system experience a minimum loss of load which promotes a more stable operation.

Furthermore, such a fault current limiter with an X_{FCL}/R_{FCL} ratio of equal to or less than 30 provides additional benefits. One additional benefit is a reduction in transient overvoltage for a circuit breaker in the power system such as the circuit breaker 108 of FIG. 4A. A transient overvoltage condition may occur for loads 110 that are more inductive in nature as the circuit breaker 108 opens to interrupt such an inductive circuit. The amplitude of the transient overvoltage may be as great as two times the rated voltage. For example, for a rated 13.8 kV circuit breaker the transient overvoltage may be as high as 27.6 kV. In contrast, with a fault current limiter with an X_{FCL}/R_{FCL}, ratio of equal to or less than 30 positioned as illustrated in FIG. 4, the circuit breaker 108 may experience transient overvoltage of only 20% higher than the rated voltage or about 16.56 kV for a 13.8 kV rating.

Yet another benefit of a fault current limiter with an X_{FCL}/R_{FCL} ratio of equal to or less than 30, is that is reduces the rate of rise of recovery voltage (RRRV) for the circuit breaker, which is the slope of the transient recovery voltage at the instant of current interruption.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes.

What is claimed is:

1. A fault current limiter, comprising
a superconducting fault current limiter, and
a shunt reactor in parallel with said superconducting fault current limiter,
wherein said fault current limiter has a fault current limiter impedance (Z_{FCL}) having a real part (R_{FCL}) and an imaginary part (X_{FCL}), wherein the ratio of said imaginary part (X_{FCL}) to said real part (R_{FCL}) is less than or equal to 30 during a fault condition.

2. The fault current limiter of claim 1, wherein said shunt reactor has a reactor impedance (Z_{SH}) having a real part (R_{SH}) and an imaginary part (X_{SH}), and wherein said fault current limiter impedance (Z_{FCL}) is roughly equal to said reactor impedance (Z_{SH}) during a fault condition.

3. The fault current limiter of claim 1, wherein said superconducting fault current limiter has a superconducting impedance (Z_{SC}) having a real part (R_{SC}) and an imaginary part (X_{SC}), and wherein said real part of said superconducting impedance (R_{SC}) is roughly equal to 0 during normal operation.

4. The fault current limiter of claim 3, wherein said real part of said superconducting impedance (R_{SC}) increases during a fault condition, so as to limit the current through said superconducting fault current limiter.

5. A method of improving power system transient stability during a fault condition, comprising:
providing a fault current limiter coupled in series between a power generator and a load, wherein said fault current limiter has a fault current limiter impedance (Z_{FCL}) having a real part (R_{FCL}) and an imaginary part (X_{FCL}), wherein the ratio of said imaginary part (X_{FCL}) to said real part (R_{FCL}) is less than or equal to 30 during a fault condition.

6. The method of claim 5, wherein said fault current limiter impedance (Z_{FCL}) is roughly equal to 0 under normal operation.

7. The method of claim 5, further comprising providing a circuit breaker in series between said fault current limiter and said load, such that said circuit breaker opens upon detection of a fault condition.

8. The method of claim 7, wherein said circuit breaker experiences transient overvoltage of about 20% during a fault condition.

9. The method of claim 5, wherein said power generator delivers a first amount of power to said load during normal operation and a second amount of power to said fault current limiter during a fault condition, and said ratio minimizes the difference between said first amount and said second amount.

10. A power system, comprising:
a power generator
a load
a fault current limiter coupled in series between said power generator and said load, wherein said fault current limiter has a fault current limiter impedance (Z_{FCL}) having a real part (R_{FCL}) and an imaginary part (X_{FCL}), wherein the ratio of said imaginary part (X_{FCL}) to said real part (R_{FCL}) is less than or equal to 30 during a fault condition.

11. The power system of claim 10, wherein said fault current limiter comprises:
a superconducting fault current limiter, and
a shunt reactor in parallel with said superconducting fault current limiter.

12. The power system of claim 11, wherein said shunt reactor has a reactor impedance (Z_{SH}) having a real part (R_{SH}) and an imaginary part (X_{SH}), and wherein said fault current limiter impedance (Z_{FCL}) is roughly equal to said reactor impedance (Z_{SH}) during a fault condition.

13. The power system of claim 11, wherein said superconducting fault current limiter has a superconducting impedance (Z_{SC}) having a real part (R_{SC}) and an imaginary part (X_{SC}), and wherein said real part of said superconducting impedance (R_{SC}) is roughly equal to 0 during normal operation.

14. The power system of claim 13, wherein said real part of said superconducting impedance (R_{SC}) increases during a fault condition, so as to limit the current through said superconducting fault current limiter.

15. The power system of claim 10, further comprising a circuit breaker coupled in series between said fault current limiter and said load.

16. The power system of claim 15, wherein said circuit breaker experiences a transient overvoltage of about 20% during a fault condition.
